(19) United States
(12) Patent Application Publication
(10) Pub. No.: US 2024/0274516 A1
(43) Pub. Date: Aug. 15, 2024

(54) INTERPOSER WITH SOLDER RESIST POSTS

(71) Applicant: QUALCOMM Incorporated, San Diego, CA (US)

(72) Inventors: Joan Rey Villarba BUOT, Escondido, CA (US); Zhijie WANG, San Diego, CA (US); Hong Bok WE, San Diego, CA (US); Sang-Jae LEE, San Diego, CA (US)

(21) Appl. No.: 18/168,420

(22) Filed: Feb. 13, 2023

(51) Int. Cl. H01L 23/498; H01L 23/29; H01L 23/373

(52) U.S. Cl. CPC H01L 23/49816; H01L 23/293; H01L 23/3737

(57) ABSTRACT

Disclosed are apparatuses and methods for fabricating the apparatuses. In an aspect, an apparatus may include: an interposer including a first metal layer, a second metal layer, a plurality of vias configured to thermally and electrically couple the first metal layer and the second metal layer, and a plurality of solder resist posts disposed on a bottom surface portion of the second metal layer; a package substrate; a die electrically coupled to the package substrate; and a thermal interface material (TIM) disposed on the die, where the TIM is configured to thermally coupled the die and the bottom surface portion of the second metal layer.

### TECHNICAL FIELD

The present disclosure generally relates to apparatuses including semiconductor structures including fabrication methods thereof, and more particularly, to a semiconductor structure including an interposer having a plurality of solder resist posts.

### BACKGROUND

Integrated circuit technology has achieved great strides in advancing computing power through miniaturization of active components. The various packaging technologies can be found in many electronic devices, including processors, servers, radio frequency (RF) integrated circuits, etc. Advanced packaging and processing techniques allow for complex devices, such as multi-die devices and system on a chip (SOC) devices, which. may include multiple function blocks, with each function block designed to perform a specific function, such as, for example, a microprocessor function, a graphics processing unit (GPU) function, a communications function (e.g., Wi-Fi, Bluetooth, and other communications), and the like.

Integrated circuits (ICs) are becoming more prevalent in electronic devices. An IC may be implemented in the form of an IC die (or an IC chip, or simply a die or a chip) that has a set of electronic circuits integrated thereon. In some implementations, an IC die includes a semiconductor substrate, various electrical components (e.g., transistors, resistors, capacitors, and/or inductors) on the substrate, and various conductive structures connecting the electrical components to form the set of electronic circuits. The manufacturing processes for fabricating the electrical components may be collectively referred to as the front end of line (FEOL) process. The manufacturing processes for forming a portion of the conductive structures in the form of layers of conductive lines and vias may be collectively referred to as the back end of line (BEOL) process. In some applications, the processes for forming another portion of the conductive structures (e.g., contacts/connectors) that connects the electrical components and the layers of conductive lines and vias may be collectively referred to as the middle of line (MOL) process.

With the development of the manufacturing technology, the size of semiconductor devices shrinks together with the decrease of the component sizes. Package on a package (PoP) is an integrated circuit packaging method to vertically combine discrete logic and memory to reduce the semiconductor device size in molded embedded package/molded embedded package on package (MEP) and other semiconductor device technologies. For example, high performance mobile devices use PoP package structures, but conventional designs are poor in thermal performance. Thermal management is an ongoing challenge for modern electronics with decreasing device size and increasing power density. As the processing demands increase and/or package size is reduced (e.g., faster processors, memory, etc.) thermal performance decreases in conventional MEP types of package structures.

Accordingly, there is a need for systems, apparatuses and methods that overcome the deficiencies of conventional semiconductor device designs including the methods, systems and apparatuses provided herein in the following disclosure.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an apparatus may include: an interposer including a first metal layer, a second metal layer, a plurality of vias configured to thermally and electrically couple the first metal layer and the second metal layer, and a plurality of solder resist posts disposed on a bottom surface portion of the second metal layer; a package substrate; a die electrically coupled to the package substrate; and a thermal interface material (TIM) disposed on the die, where the TIM is configured to thermally coupled the die and the bottom surface portion of the second metal layer.

In an aspect, a method of manufacturing an apparatus may include: forming an interposer including a first metal layer, a second metal layer, a plurality of vias configured to thermally and electrically couple the first metal layer and the second metal layer, and a plurality of solder resist posts disposed on a bottom surface portion of the second metal layer; providing a package substrate; providing a die electrically coupled to the package substrate; and depositing a thermal interface material (TIM) on the die, where the TIM is configured to thermally couple the die and the bottom surface portion of the second metal layer.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates an apparatus in accordance with one or more aspects of the disclosure.

FIGS. 2A-2B illustrate portions of an apparatus fabricated in accordance with one or more aspects of the disclosure.

FIGS. 3A-3J illustrate an example partial method for manufacturing an apparatus in accordance with one or more aspects of the disclosure.

FIG. 4 illustrates a flowchart of a method for manufacturing an apparatus in accordance with one or more aspects of the disclosure.

FIG. 5 illustrates a mobile device in accordance with one or more aspects of the disclosure.

FIG. 6 illustrates various electronic devices that may be various apparatuses in accordance with one or more aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, terms such as approximately, generally, and the like indicate that the examples provided are not intended to be limited to the precise numerical values or geometric shapes and include normal variations due to, manufacturing tolerances and variations, material variations, and other design considerations.

As noted in the foregoing, various aspects relate generally to apparatuses including PoP devices including an interposer having a plurality of solder resist posts (SR posts) and a thermal interface material (TIM) disposed on a die to provide improved thermal coupling between the die and the interposer.

Particular aspects of the subject matter described in this disclosure can be implemented to realize one or more of the following potential advantages. In some examples, an exposed bottom surface portion (i.e., exposed copper (Cu) plane on bottom side) of the interposer is provided with a plurality of SR posts disposed on the bottom surface portion. The SR posts provide support between interposer and the die (e.g., an SOC die) with the TIM disposed on top of the die. The TIM allows for heat dissipation from the die to interposers. The SR posts may be formed in an array uniformly disposed on the bottom opening in the second metal layer (M2 layer) of the interposer by standard SR exposure/development processes. In an aspect, the SR posts provides for a reduction of the TIM to copper delamination. These and other advantages and alternatives will be appreciated from the following disclosure, associated figures and claims.

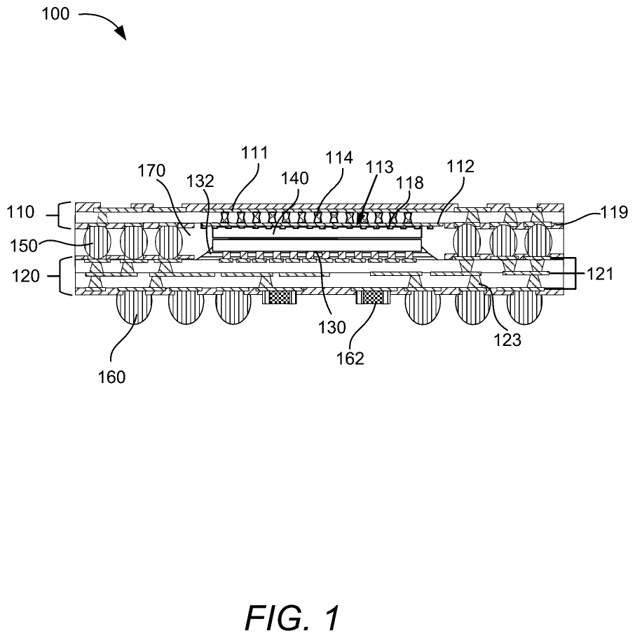

FIG. 1 illustrates an example apparatus 100, according to aspects of the disclosure. In some aspects, as shown in FIG. 1, the apparatus 100 includes an interposer 110, a package substrate 120, a die 130 and a TIM 140 disposed on the die and thermally coupled to the die 130 and the interposer 110. As used herein, the interposer 110 is configured to electrically couple the package substrate 120 and in some aspects the die 130 through the package substrate to another package (e.g., die, package substrate and optionally additional components), package substrate and/or die. The interposer 110 can considered a substrate interposer because it is configured to be electrically couple to the package substrate 120. The interposer 110 includes a first metal layer 111, a second metal layer 112, a plurality of interposer vias 114 thermally coupling the first metal layer 111 and the second metal layer 112. A plurality of solder resist posts 118 (SR posts) are disposed on a bottom surface portion 113 of the second metal layer 112. The bottom surface portion 113 is exposed as it is not covered in the bottom solder resist 119, however portions are covered by the SR posts 118, as will be discussed further below. The bottom surface portion 113 of the second metal layer 112 is thermally coupled to the die 130 through the TIM 140. Specifically, the portions of the TIM 140 that extend between the SR posts 118 provide the thermal conduction path to the bottom surface portion 113 of the second metal layer 112 and the plurality of interposer vias 114 provide the thermal coupling to the first metal layer 111, which allows for the heat dissipation from the die 130 over both metal layers (first metal layer 111 and second metal layer 112) of the interposer 110. In some aspects, the TIM 140 is at least one of a thermal paste or thermal film. In some aspects, the TIM 140 is a polymer thermal interface material (PTIM), such as ShinEtsu G-769EL or other similar materials. In contrast to conventional designs which have a mold compound (such as mold compound 170) disposed between the die and interposer, the various aspects disclosed herein provide for improved heat dissipation from the die 130 through TIM 140 and the exposed bottom surface portion 113.

As illustrated in FIG. 1, the die 130 is electrically coupled to the package substrate 120 and an underfill 132 provides additional mechanical coupling between the die 130 and the package substrate 120. The interposer 110 is electrically coupled to a top side of the package substrate 120 by a plurality of interposer connectors 150. The interposer connectors 150 may be copper pillars, copper balls, solder, solder balls, combinations thereof or any suitable connector. A mold compound 170 disposed between the interposer 110 and the package substrate 120 encapsulates the interposer connectors 150, the die 130 and the TIM 140. A plurality of package connectors 160 is disposed on a bottom surface portion of the package substrate opposite the plurality of interposer connectors 150. In some aspects, the plurality of package connectors 160 is a ball grid array (BGA). In other aspects, the plurality of package connectors 160 may be copper pillars, copper balls, solder, solder balls, combinations thereof or any suitable connector. The plurality of package connectors 160 provides for connections to external devices and electrical coupling to the die 130 and interposer 110 through the metal layers 121 and vias 123. Additional components 162 may be electrically coupled to the package substrate, such as resistors, capacitors, inductors, and any other component specified in the various design configurations.

It will be appreciated that the illustrated configuration and descriptions provided herein are merely to aid in the explanation of the various aspects disclosed herein. For example, there may be one or more dies in the apparatus 100. Further, the design may have more or less metal layers and vias in the package substrate 120 and/or the interposer 110, additional components may be provided, etc. Accordingly, the forgoing illustrative examples and associated figures should not be construed to limit the various aspects disclosed and claimed herein.

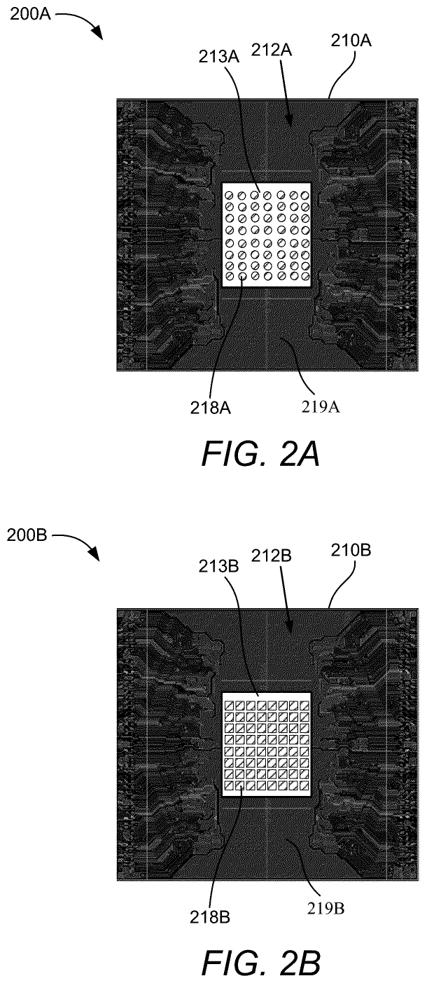

FIG. 2A illustrates a portion of example apparatus 200A according to aspects of the disclosure. The elements of the apparatus 200A that are the same or similar to those of the apparatus 100 are given similar reference numbers and for some elements the labeling and detailed description thereof may be omitted.

As shown in FIG. 2A, the interposer 210A includes a second metal layer 212A (traces visible below a bottom solder resist 219A) and a plurality of interposer vias (not visible) thermally coupling a first metal layer (not visible) and the second metal layer 212A. A plurality of solder resist posts 218A (SR posts) are disposed on a bottom surface portion 213A of the second metal layer 212A. The bottom surface portion 213A is exposed as it is not covered in the bottom solder resist 219A, however portions are covered by the SR posts 218A. It will be appreciated that the SR posts 218A are formed from the same material as bottom solder resist 219A and has a similar height/thickness. In the bottom view presented here the SR posts 218A have a circular shape. The SR posts 218A are formed in the illustrated aspect as an array of circular posts. The SR posts 218A help to mitigate any copper delamination of the exposed bottom surface portion 213A during the fabrication process, but still allows for the portions of the bottom surface portion 213A to be open for thermal coupling with the TIM, as discussed above. It will be appreciated that in some aspects the SR posts 218A have a size (diameter) of approximately 100 micrometers (um). In some aspects, the plurality of SR posts 218A is formed in an array and has a pitch of approximately 200 micrometers (um). In some aspects, the SR posts 218A have a size (diameter) in a range of 50 um to 100 um. In some aspects, the plurality of SR posts 218A is formed in an array and has a pitch in a range of 100 um to 200 um. It will be appreciated that these dimensions are merely provided as an example and should not be construed to limit the various aspects disclosed or claimed herein.

FIG. 2B illustrates a portion of example apparatus 200B according to aspects of the disclosure. The elements of the apparatus 200B that are the same or similar to those of the apparatus 100 and 200A are given similar reference numbers and for some elements the labeling and detailed description thereof may be omitted.

As shown in the FIG. 2B, the interposer 210B includes a second metal layer 212B (traces visible below a bottom solder resist 219B) and a plurality of interposer vias (not visible) thermally coupling a first metal layer (not visible) and the second metal layer 212B. A plurality of solder resist posts 218B (SR posts) are disposed on a bottom surface portion 213B of the second metal layer 212B. The bottom surface portion 213B is exposed as it is not covered in the bottom solder resist 219B, however portions are covered by the SR posts 218B. It will be appreciated that the SR posts 218B are formed from the same material as bottom solder resist 219B and has a similar height/thickness. In the bottom view presented here the SR posts 218B have a generally rectangular shape (in this example generally square). In this aspect, the SR posts 218B are formed in the illustrated aspect as an array of rectangular (square) posts. The SR posts 218B help to mitigate any copper delamination of the exposed bottom surface portion 213B during the fabrication process, but still allows for the portions of the bottom surface portion 213B to be open for thermal coupling with the TIM, as discussed above. It will be appreciated that in some aspects the SR posts 218B have a size (sides) of approximately 100 micrometers (um). In some aspects, the plurality of SR posts 218B is formed in an array and has a pitch of approximately 200 micrometers (um). In some aspects, the SR posts 218B have a size (sides) of in a range of 50 um to 100 um. In some aspects, the plurality of SR posts 218B is formed in an array and has a pitch in a range of 100 um to 200 um. It will be appreciated that these dimensions are merely provided as an example and should not be construed to limit the various aspects disclosed or claimed herein. Further, it will be appreciated that the various aspects are not limited to a specific SR posts design and in various aspects the SR posts may be circular, oval, rectangular, triangular, irregular or combinations thereof. Likewise, the size and pitch may be uniform or non-uniform and may be different from the example values provided. It will be appreciated that these dimensions and geometric shapes are merely provided as an example and should not be construed to limit the various aspects disclosed or claimed herein.

In order to fully illustrate aspects of the design of the present disclosure, methods of fabrication are presented. Other methods of fabrication are possible, and the discussed fabrication methods are presented only to aid understanding of the concepts disclosed herein.

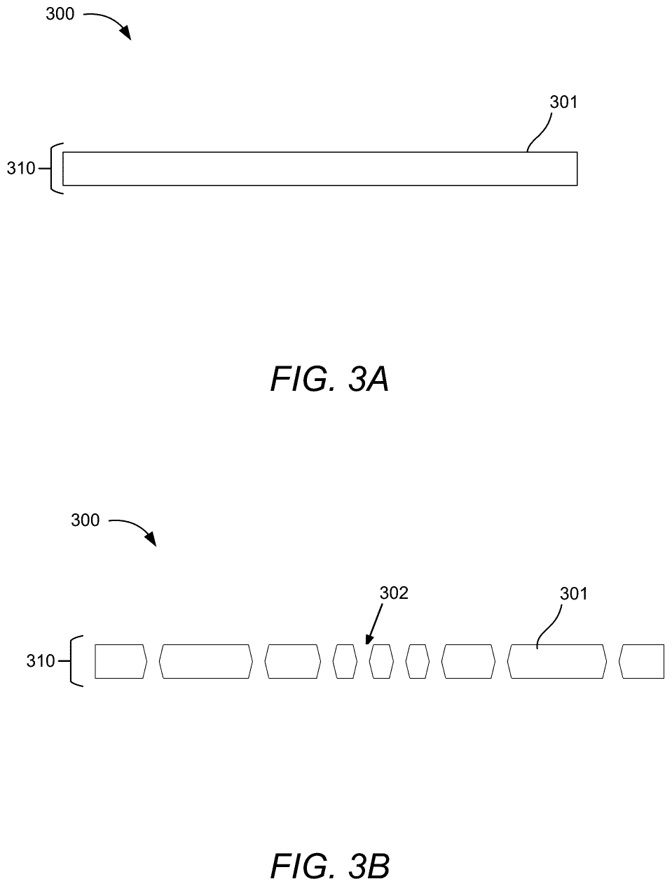

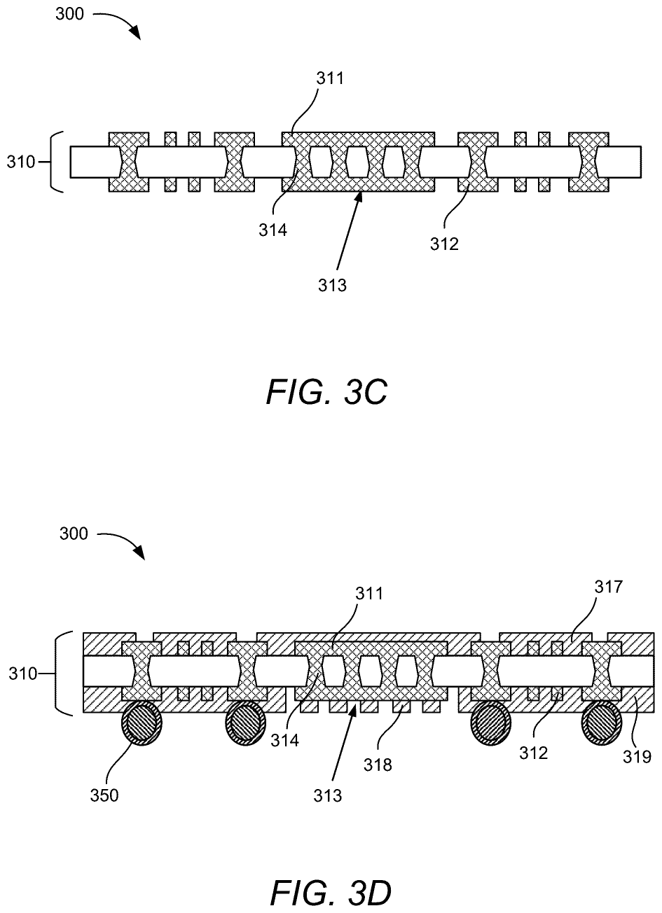

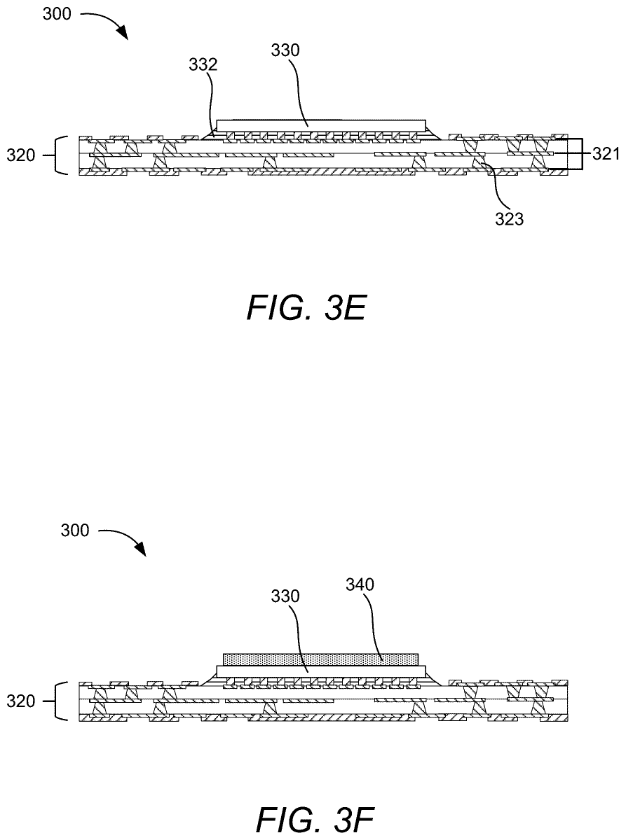

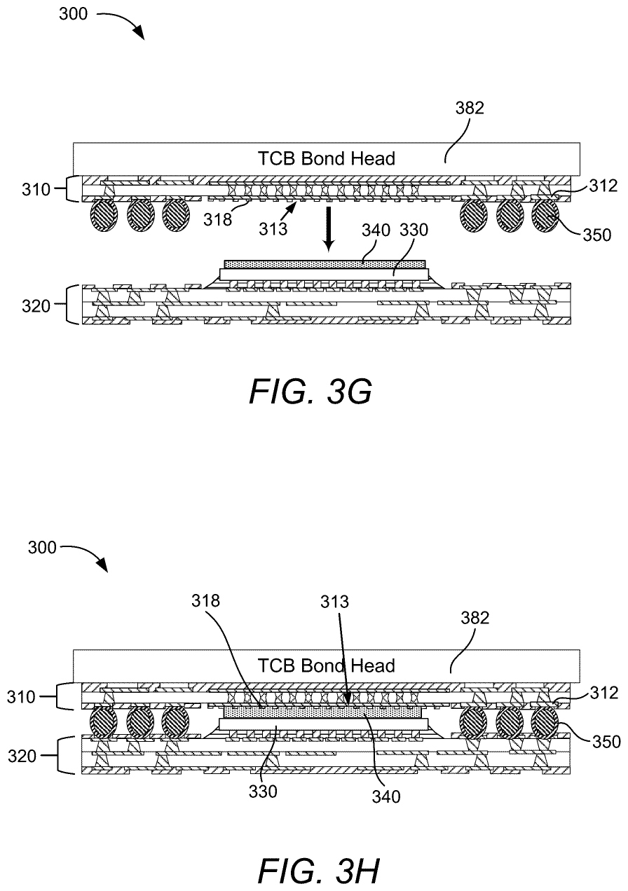

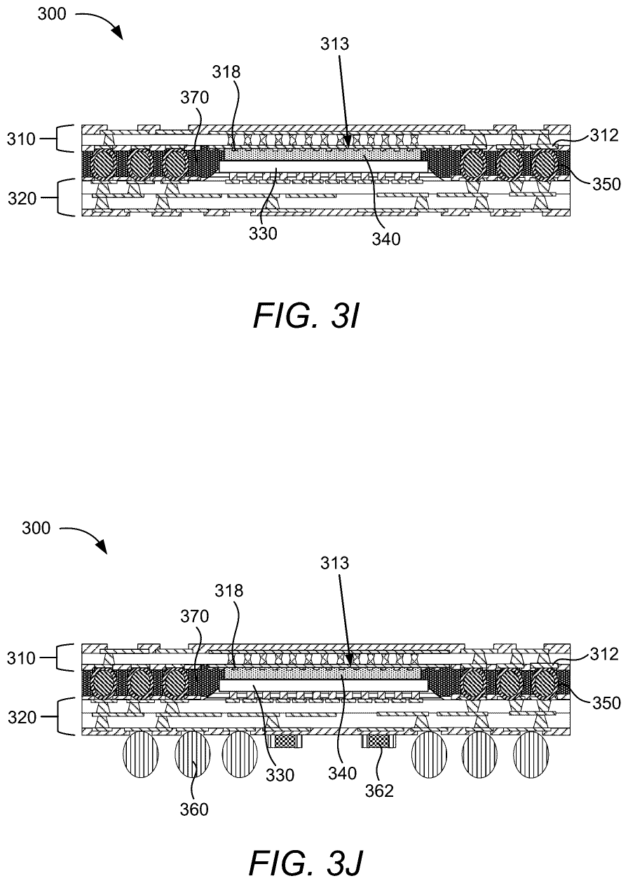

FIGS. 3A-3J illustrate an example partial method for manufacturing an apparatus (such as 100, 200A and 200B discussed above), according to one or more aspects of the disclosure. Many of the elements illustrated in FIGS. 3A-3J that are the same or similar to those of the apparatuses 100, 200A and 200B, are given the same or similar reference numbers, and the detailed description thereof may be omitted.

As shown in FIG. 3A, in some aspects, the process of manufacturing apparatus 300 starts with providing a base substrate 301 of the interposer 310. In some aspects the base substrate 301 may be a copper clad laminate (CCL), pre-impregnated glass (PPG) or other suitable base material.

As shown in FIG. 3B, in some aspects, the process of manufacturing apparatus 300 continues with via formation in the base substrate 301 of the interposer 310. In some aspects, base substrate 301 may be patterned and etched, drilled, or fabricated using other conventional techniques to form the via openings 302.

As shown in FIG. 3C, in some aspects, the process of manufacturing apparatus 300 continues with copper plating and patterning of the interposer 310. As illustrated, after the copper plating and patterning, the interposer 310 includes a first metal layer 311, a second metal layer 312 and a plurality of interposer vias 314 that thermally and electrically couple the first metal layer 311 and the second metal layer 312. A bottom surface portion 313 of the second metal layer 312 is the portion that will be exposed in future processing as it will not be covered in solder resist.

As shown in FIG. 3D, in some aspects, the process of manufacturing apparatus 300 continues with solder resist processing including lamination, exposure and developing which forms the top solder resist 317 and bottom solder resist 319 of the interposer 310. As illustrated, after the solder resist processing, the interposer 310 includes a first metal layer 311, a second metal layer 312 and a plurality of interposer vias 314 that thermally and electrically couple the first metal layer 311 and the second metal layer 312. The bottom surface portion 313 is exposed as it is not covered in the bottom solder resist 319. A plurality of solder resist posts 318 (SR posts) are disposed on the bottom surface portion 313 of the second metal layer 312. As discussed above, various shapes sizes and patterns may be used for the SR posts 318. Finally, a plurality of interposer connectors 350 may be attached to the second metal layer 312 of the interposer 310. The interposer connectors 350 may be copper pillars, copper balls, solder, solder balls, combinations thereof or any suitable connector.

As shown in FIG. 3E, in some aspects, the process of manufacturing apparatus 300 continues with providing a die 330 electrically coupled to a package substrate 320 and having an underfill 332 that provides additional mechanical coupling between the die 330 and the package substrate 320. The package substrate 320 includes metal layers 321 and vias 323 which provides for electrical connections to external devices and to the die 330.

As shown in FIG. 3F in some aspects, the process of manufacturing apparatus 300 continues with depositing a TIM 340 on the die 330 disposed on the package substrate 320. The TIM 340 is configured to allow for thermal coupling to the die 330. In some aspects, the TIM 340 is at least one of a thermal paste that may be applied to the die 330 through a dispensing device. In some aspects, the TIM 340 is a thermal film. In some aspects, the TIM 340 is a polymer thermal interface material (PTIM), such as ShinEtsu G-769EL or other similar materials.

As shown in FIG. 3G, in some aspects, the process of manufacturing apparatus 300 continues with the interposer 310 attached to a thermo-compression bonding (TCB) head 382. The attachment is performed in preparation for TCB processing. Specifically, the TCB process is performed to attach interposer 310 with the interposer connectors 350 to the package substrate 320 and the die 330 with TIM 340 deposited. The interposer 310 is configured as illustrated and discussed in relation to FIG. 3D, including a plurality of SR posts 318 disposed on the bottom surface portion 313 of the second metal layer 312 of interposer 310.

As shown in FIG. 3H, in some aspects, the process of manufacturing apparatus 300 continues with the interposer 310 attached to the TCB head 382 and the TCB process being performed. During the TCB process, process parameters, such as temperature, force and displacement are continuously monitored to provide for bonding of the various components. As illustrated, the TCB head 382 can provide heat, force, and displacement to bond the interposer connectors 350 to the package substrate 320. Additionally, the TIM 340 is bonded, through openings between the SR posts 318, to the bottom surface portion 313 of the second metal layer 312 of interposer 310. As discussed herein, the TIM 340 provides a thermal coupling between the die 330 and interposer 310.

As shown in FIG. 3I, in some aspects, the process of manufacturing apparatus 300 continues with the interposer 310 being removed from the TCB head 382 (not illustrated). After the TCB process, the interposer connectors 350 are electrically coupled to the package substrate 320 and the interposer 310. Additionally, the TIM 340 is bonded to the die 330, and through openings between the SR posts 318, to the bottom surface portion 313 of the second metal layer 312 of interposer 310. The mold compound 370 is deposited between the interposer 310 and the package substrate 320 and encapsulates the interposer connectors 350, the die 330 and the TIM 340.

As shown in FIG. 3J, in some aspects, the process of manufacturing apparatus 300 continues with attaching package connectors 360. The process can begin with the interposer connectors 350 coupling the interposer 310 to the package substrate 320. Additionally, the TIM 340 is bonded to the die 330, and through openings between the SR posts 318, to the bottom surface portion 313 of the second metal layer 312 of interposer 310. The mold compound 370 disposed between the interposer 310 and the package substrate 320 encapsulates the interposer connectors 350, the die 330 and the TIM 340. The package connectors 360 are disposed on a bottom surface portion of the package substrate 320 opposite the plurality of interposer connectors 350. In some aspects, the plurality of package connectors 360 is a ball grid array (BGA) and may be attached to the package substrate 320 through a reflow process. In other aspects, the plurality of package connectors 360 may be copper pillars, copper balls, solder, solder balls, combinations thereof or any suitable connector. Additional components 362 may be electrically coupled to the package substrate 320, such as resistors, capacitors, inductors and/or any other component specified in the various design configurations. As the configuration of apparatus 300 is similar to that of apparatus 100 discussed above, some similar elements illustrated will be not label and/or described in detail.

It will be appreciated that the foregoing fabrication/manufacturing process was provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

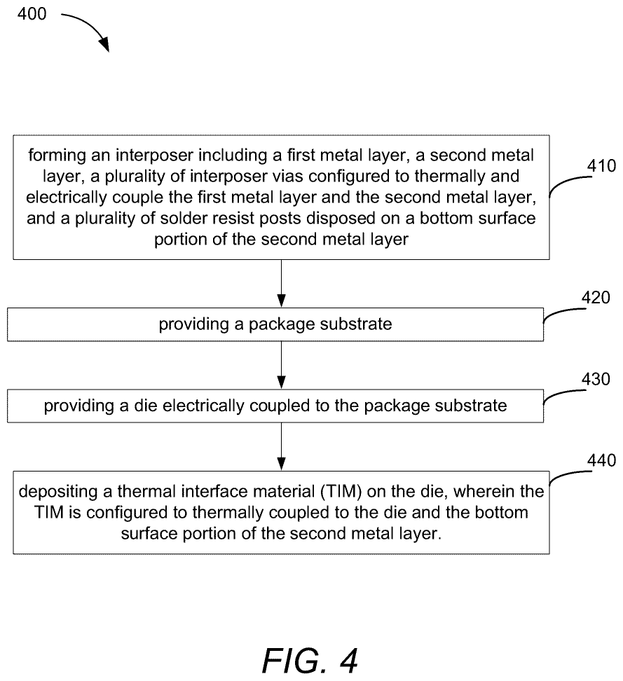

FIG. 4 illustrates a method 400 for fabricating an apparatus (such as the apparatuses 100, 200A, 200B or 300), according to aspects of the disclosure. At operation 410, an interposer (e.g., interposer 110 or 310) is formed including a first metal layer, a second metal layer, a plurality of interposer vias configured to thermally and electrically couple the first metal layer and the second metal layer, and a plurality of solder resist posts disposed on a bottom surface portion of the second metal layer.

At operation 420, the method continues with providing a package substrate (e.g., package substrate 120 or 320). In some aspects the package substrate may be provided as a separate component or may be fabricated as part of the overall fabrication process. The package substrate has a plurality of metal layer and vias interconnecting the metal layer. Additionally, pads or openings in the solder resist are provided for connections to the interposer, as discussed and illustrated in the foregoing disclosure and accompanying drawings.

At operation 430, the method continues with providing a die electrically coupled to the package substrate (e.g., die 130 or 330 and package substrate 120 or 320). In some aspects, the die and package substrate may be provided as an assembled component. In some aspects, the die and package substrate may be provided as separate components and electrically coupled as part of the fabrication process. In some aspects, the die and package substrate may be fabricated as part of the overall fabrication process. It will be appreciated that multiple fabricators and/or fabrication facilities may be used to provide the die, package substrate and/or the die electrically coupled to the package substrate as a component.

At operation 440, the method continues with depositing a thermal interface material (TIM) on the die (e.g., die 130 or 330 and TIM 140 or 340). The TIM is configured to thermally couple the die and the bottom surface portion of the second metal layer. In some aspects, the TIM may be one of a thermal paste or thermal film. In some aspects, the TIM is a polymer thermal interface material (PTIM).

As discussed above, various other process steps may be performed to provide the final apparatus, such as the thermal bonding and package connector attachment, as discussed above. Additional processing/fabrication may include coupling additional dies (e.g., memory) or components to the interposer, marking, package singulation and other conventional processes to provide the finished apparatus. Further, it will be appreciated that, in accordance with the various aspects disclosed, the apparatus may include various configurations and may be a PoP, a molded embedded package on package (MEP), integrated electronic component, or complete device, such as a mobile device, and other devices discussed herein. Accordingly, it will be appreciated from the foregoing disclosure that additional processes for fabricating the various aspects disclosed herein will be apparent to those skilled in the art and a literal rendition of the processes discussed above will not be provided or illustrated in the included drawings. It will be appreciated that the sequences of the fabrication processes are not necessarily in any order and later processes may be discussed earlier for convenience and to provide an example of the breadth of the various aspects disclosed.

The foregoing disclosed devices and functionalities may be designed and stored in computer files (e.g., register-transfer level (RTL), Geometric Data Stream (GDS) Gerber, and the like) stored on computer-readable media. Some or all such files may be provided to fabrication handlers, fabricators, and/or fabrication facilities to fabricate devices based on such files. Resulting products may include various components, including semiconductor wafers that are then cut into semiconductor die and packaged into semiconductor packages, integrated devices, PoP devices, system-on-chip devices, and the like, which may then be employed in the various devices described herein.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

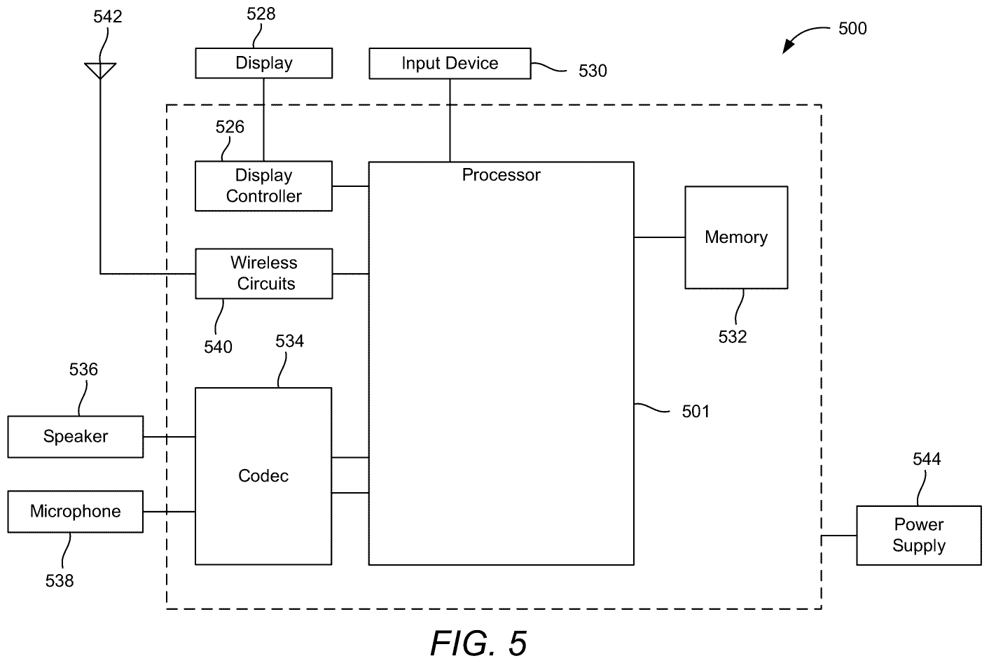

FIG. 5 illustrates a mobile device 500, according to aspects of the disclosure. In some aspects, the mobile device 500 may be implemented by including one or more ICs including the semiconductor structures (e.g., PoP structure) as disclosed herein.

In some aspects, mobile device 500 may be configured as a wireless communication device. As shown, mobile device 500 includes processor 501. Processor 501 may be communicatively coupled to memory 532 over a link, which may be a die-to-die or chip-to-chip link. Mobile device 500 also includes display 528 and display controller 526, with display controller 526 coupled to processor 501 and to display 528. The mobile device 500 may include input device 530 (e.g., physical, or virtual keyboard), power supply 544 (e.g., battery), speaker 536, microphone 538, and wireless antenna 542. In some aspects, the power supply 544 may directly or indirectly provide the supply voltage for operating some or all of the components of the mobile device 500.

In some aspects, FIG. 5 may include coder/decoder (CODEC) 534 (e.g., an audio and/or voice CODEC) coupled to processor 501; speaker 536 and microphone 538 coupled to CODEC 534; and wireless circuits 540 (which may include a modem, RF circuitry, filters, etc.) coupled to wireless antenna 542 and to processor 501.

In some aspects, one or more of processor 501 (e.g., SoCs, application processor (AP)), display controller 526, memory 532, CODEC 534, and wireless circuits 540 (e.g., baseband interface) including semiconductor structures (e.g., PoP structures/components) according to the various aspects described in this disclosure.

It should be noted that although FIG. 5 depicts a mobile device 500, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

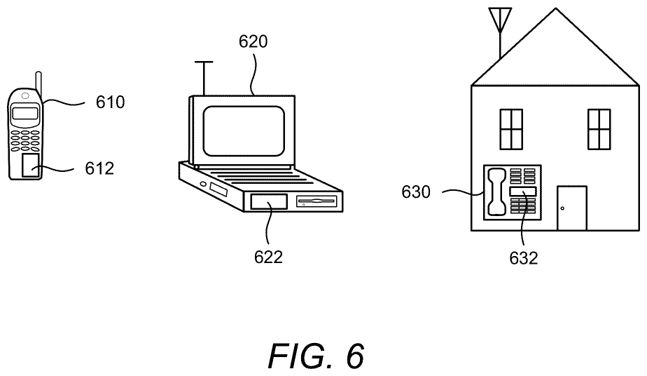

FIG. 6 illustrates various electronic devices 610, 620, and 630 that may be integrated with ICs 612, 622, and 632, (e.g., including PoP structures/components) according to aspects of the disclosure. For example, a mobile phone device 610, a laptop computer device 620, and a fixed location terminal device 630 may each be considered generally user equipment (UE) and may include one or more ICs, such as ICs 612, 622, and 632, and a power supply to provide the supply voltages to power the ICs. The ICs 612, 622, and 632 may be, for example, correspond to an IC including semiconductor structures manufactured based on the examples described above with reference to FIGS. 1, 2A-2B, and 3A-3J.

The devices 610, 620, and 630 illustrated in FIG. 6 are merely non-limiting examples. Other electronic devices may also feature the ICs including semiconductor structures as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1-6 may be rearranged and/or combined into a single component, process, feature, or function or incorporated in several components, processes, or functions. Additional elements, components, processes, and/or functions may also be added without departing from the disclosure. In some implementations, FIGS. 1-6 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (PoP) device, and the like.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. UEs can be embodied by any of a number of types of devices including but not limited to printed circuit (PC) cards, compact flash devices, external or internal modems, wireless or wireline phones, smartphones, tablets, consumer tracking devices, asset tags, and so on.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart).

Nothing stated or illustrated depicted in this application is intended to dedicate any component, action, feature, benefit, advantage, or equivalent to the public, regardless of whether the component, action, feature, benefit, advantage, or the equivalent is recited in the claims.

Further, those of skill in the art will appreciate that the various illustrative logical blocks, modules, circuits, and algorithm actions described in connection with the examples disclosed herein may be implemented as electronic hardware, computer software, or combinations of both. To clearly illustrate this interchangeability of hardware and software, various illustrative components, blocks, modules, circuits, and actions have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Although some aspects have been described in connection with a device, it is understood that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer, or an electronic circuit. In some examples, some or a plurality of the most important method actions can be performed by such an apparatus.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An apparatus comprising: an interposer including a first metal layer, a second metal layer, a plurality of vias configured to thermally and electrically couple the first metal layer and the second metal layer, and a plurality of solder resist posts disposed on a bottom surface portion of the second metal layer; a package substrate; a die electrically coupled to the package substrate; and a thermal interface material (TIM) disposed on the die, wherein the TIM is configured to thermally coupled the die and the bottom surface portion of the second metal layer.

Clause 2. The apparatus of clause 1, wherein the TIM is at least one of a thermal paste or thermal film.

Clause 3. The apparatus of any of clauses 1 to 2, wherein the TIM is a polymer thermal interface material (PTIM).

Clause 4. The apparatus of any of clauses 1 to 3, wherein the plurality of solder resist posts is at least one of circular, oval, rectangular, triangular, irregular or combinations thereof.

Clause 5. The apparatus of any of clauses 1 to 4, wherein the plurality of solder resist posts has a size of approximately 50 micrometers (um) to 100 um.

Clause 6. The apparatus of any of clauses 1 to 5, wherein the plurality of solder resist posts is an array.

Clause 7. The apparatus of clause 6, wherein the plurality of solder resist posts has a pitch of approximately 100 micrometers (um) to 200 um.

Clause 8. The apparatus of any of clauses 1 to 7, further comprising: a plurality of interposer connectors configured to electrically couple the interposer to the package substrate.

Clause 9. The apparatus of clause 8, wherein the plurality of interposer connectors is at least one of copper pillars, copper balls, solder, solder balls, or combinations thereof.

Clause 10. The apparatus of any of clauses 8 to 9, further comprising: a mold compound disposed between the interposer and the package substrate.

Clause 11. The apparatus of clause 10, wherein the mold compound encapsulates the plurality of interposer connectors, the die, and the TIM.

Clause 12. The apparatus of any of clauses 10 to 11, further comprising: a plurality of package connectors disposed on a bottom surface portion of the package substrate opposite the plurality of interposer connectors.

Clause 13. The apparatus of clause 12, wherein the plurality of package connectors is a ball grid array (BGA).

Clause 14. The apparatus of any of clauses 1 to 13, wherein the apparatus comprises a package on a package (PoP) device.

Clause 15. The apparatus of any of clauses 1 to 14, wherein the apparatus comprises at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of Things (IoT) device, a laptop computer, a server, an access point, a base station, or a device in an automotive vehicle.

Clause 16. A method of manufacturing an apparatus, comprising: forming an interposer including a first metal layer, a second metal layer, a plurality of vias configured to thermally and electrically couple the first metal layer and the second metal layer, and a plurality of solder resist posts disposed on a bottom surface portion of the second metal layer; providing a package substrate; providing a die electrically coupled to the package substrate; and depositing a thermal interface material (TIM) on the die, wherein the TIM is configured to thermally couple the die and the bottom surface portion of the second metal layer.

Clause 17. The method of clause 16, wherein the TIM is at least one of a thermal paste or thermal film.

Clause 18. The method of any of clauses 16 to 17, wherein the TIM is a polymer thermal interface material (PTIM).

Clause 19. The method of any of clauses 16 to 18, wherein the plurality of solder resist posts is at least one of circular, oval, rectangular, triangular, irregular or combinations thereof.

Clause 20. The method of any of clauses 16 to 19, wherein the plurality of solder resist posts has a size of approximately 50 micrometers (um) to 100 um.

Clause 21. The method of any of clauses 16 to 20, wherein the plurality of solder resist posts is an array.

Clause 22. The method of clause 21, wherein the plurality of solder resist posts has a pitch of approximately 100 micrometers (um) to 200 um.

Clause 23. The method of any of clauses 16 to 22, further comprising: a plurality of interposer connectors configured to electrically couple the interposer to the package substrate.

Clause 24. The method of clause 23, wherein the plurality of interposer connectors is at least one of copper pillars, copper balls, solder, solder balls, or combinations thereof.

Clause 25. The method of any of clauses 23 to 24, further comprising: a mold compound disposed between the interposer and the package substrate.

Clause 26. The method of clause 25, wherein the mold compound encapsulates the plurality of interposer connectors, the die, and the TIM.

Clause 27. The method of any of clauses 25 to 26, further comprising: a plurality of package connectors disposed on a bottom surface portion of the package substrate opposite the plurality of interposer connectors.

Clause 28. The method of clause 27, wherein the plurality of package connectors is a ball grid array (BGA).

Clause 29. The method of any of clauses 16 to 28, wherein the apparatus comprises a package on a package (PoP) device.

Clause 30. The method of any of clauses 16 to 29, wherein the apparatus comprises at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of Things (IoT) device, a laptop computer, a server, an access point, a base station, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An apparatus comprising:
an interposer including a first metal layer, a second metal layer, a plurality of vias configured to thermally and electrically couple the first metal layer and the second metal layer, and a plurality of solder resist posts disposed on a bottom surface portion of the second metal layer;
a package substrate;
a die electrically coupled to the package substrate; and
a thermal interface material (TIM) disposed on the die, wherein the TIM is configured to thermally coupled the die and the bottom surface portion of the second metal layer.

2. The apparatus of claim 1, wherein the TIM is at least one of a thermal paste or thermal film.

3. The apparatus of claim 1, wherein the TIM is a polymer thermal interface material (PTIM).

4. The apparatus of claim 1, wherein the plurality of solder resist posts is at least one of circular, oval, rectangular, triangular, irregular or combinations thereof.

5. The apparatus of claim 1, wherein the plurality of solder resist posts has a size of approximately 50 micrometers (um) to 100 um.

6. The apparatus of claim 1, wherein the plurality of solder resist posts is an array.

7. The apparatus of claim 6, wherein the plurality of solder resist posts has a pitch of approximately 100 micrometers (um) to 200 um.

8. The apparatus of claim 1, further comprising:
a plurality of interposer connectors configured to electrically couple the interposer to the package substrate.

9. The apparatus of claim 8, wherein the plurality of interposer connectors is at least one of copper pillars, copper balls, solder, solder balls, or combinations thereof.

10. The apparatus of claim 8, further comprising:
a mold compound disposed between the interposer and the package substrate.

11. The apparatus of claim 10, wherein the mold compound encapsulates the plurality of interposer connectors, the die, and the TIM.

12. The apparatus of claim 10, further comprising:
a plurality of package connectors disposed on a bottom surface portion of the package substrate opposite the plurality of interposer connectors.

13. The apparatus of claim 12, wherein the plurality of package connectors is a ball grid array (BGA).

14. The apparatus of claim 1, wherein the apparatus comprises a package on a package (PoP) device.

15. The apparatus of claim 1, wherein the apparatus comprises at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of Things (IoT) device, a laptop computer, a server, an access point, a base station, or a device in an automotive vehicle.

16. A method of manufacturing an apparatus, comprising:
forming an interposer including a first metal layer, a second metal layer, a plurality of vias configured to thermally and electrically couple the first metal layer and the second metal layer, and a plurality of solder resist posts disposed on a bottom surface portion of the second metal layer;
providing a package substrate;
providing a die electrically coupled to the package substrate; and
depositing a thermal interface material (TIM) on the die, wherein the TIM is configured to thermally couple the die and the bottom surface portion of the second metal layer.

17. The method of claim 16, wherein the TIM is at least one of a thermal paste or thermal film.

18. The method of claim 16, wherein the TIM is a polymer thermal interface material (PTIM).

19. The method of claim 16, wherein the plurality of solder resist posts is at least one of circular, oval, rectangular, triangular, irregular or combinations thereof.

20. The method of claim 16, wherein the plurality of solder resist posts has a size of approximately 50 micrometers (um) to 100 um.

21. The method of claim 16, wherein the plurality of solder resist posts is an array.

22. The method of claim 21, wherein the plurality of solder resist posts has a pitch of approximately 100 micrometers (um) to 200 um.

23. The method of claim 16, further comprising:
a plurality of interposer connectors configured to electrically couple the interposer to the package substrate.

24. The method of claim 23, wherein the plurality of interposer connectors is at least one of copper pillars, copper balls, solder, solder balls, or combinations thereof.

25. The method of claim 23, further comprising:
a mold compound disposed between the interposer and the package substrate.

26. The method of claim 25, wherein the mold compound encapsulates the plurality of interposer connectors, the die, and the TIM.

27. The method of claim 25, further comprising:
a plurality of package connectors disposed on a bottom surface portion of the package substrate opposite the plurality of interposer connectors.

28. The method of claim 27, wherein the plurality of package connectors is a ball grid array (BGA).

29. The method of claim 16, wherein the apparatus comprises a package on a package (PoP) device.

30. The method of claim 16, wherein the apparatus comprises at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of Things (IoT) device, a laptop computer, a server, an access point, a base station, or a device in an automotive vehicle.
